(19) United States
(12) Patent Application Publication
(10) Pub. No.: US 2005/0093628 A1
(43) Pub. Date: May 5, 2005

(54) Differential amplifier circuit and multistage amplifier circuit

(75) Inventor: Daniel Yu-Hua Chen, Tokyo (JP)

Correspondence Address: MCDERMOTT WILL & EMERY LLP, 600 13TH STREET, N.W., WASHINGTON, DC, 20005-3096, US

(73) Assignee: MITSUBISHI DENKI KABUSHIKI KAISHA

(21) Appl. No.: 10/915,441

(22) Filed: Aug. 11, 2004

(30) Foreign Application Priority Data
Nov. 4, 2003 (JP) P 2003-374254

(51) Int. Cl. H03F 3/45

(52) U.S. Cl. 330/253

(57) ABSTRACT

A differential amplifier circuit includes: a first field-effect transistor being operable base on a non-inverted input; a first load circuit which is connected to the drain of the first field-effect transistor; a first current control circuit which is connected to the source of the first field-effect transistor; a second field-effect transistor being operable base on an inverted input; a second load circuit which is connected to the drain of the second field-effect transistor; a second current control circuit which is connected to the source of the second field-effect transistor; and a gain compensation circuit which is connected between the source of the first field-effect transistor and the source of the second field-effect transistor, thereby attaining a high-speed differential amplifier circuit with low jitters.

### BACKGROUND OF THE INVENTION

1. Field of the Invention

The present invention relates to a differential amplifier circuit and a multistage amplifier circuit using the same.

2. Description of the Related Art

In a field-effect transistor (FET) using SOI (Silicon On Insulator) process, since holes are easily accumulated inside a channel, a characteristics curve of drain current vs. drain voltage is liable to show a kink. To avoid such a kink effect, fully depleted SOI process with a body contact is employed. In such SOI process, gates and contacts have parasitic body resistances relatively larger than those of C-MOS portions.

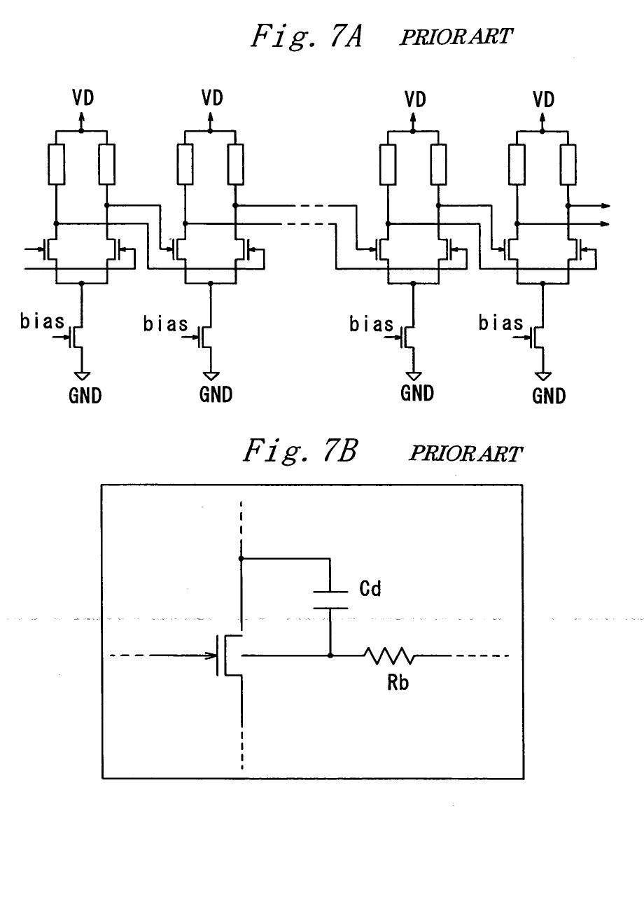

On the other hand, since a transceiver input buffer circuit with high input sensitivity requires nearly 40 dB of total gain, generally differential transistor pairs which are connected in multistage cascade, as shown in FIG. 7A, are employed.

In case the total body resistance becomes larger and a high gain is required, output waveforms are severely degraded at higher frequency region.

At lower frequency region the body contact creates a resistive discharge path, which allows excess carriers to flow out. By removing the excess carriers, the body potential decreases to attain lower output impedance.

FIG. 7B is an equivalent circuit diagram showing a parasitic capacitance and a parasitic body resistance around a MOS-FET. The parasitic capacitance Cd is created between the body node and the drain node of the FET. The parasitic body resistance Rd, as described above, is created at the body node.

The parasitic capacitance Cd dynamically coupled signals at the drain node into the body node. This longitudinal capacitive discharge path competes with the resistive discharge path, as described above, resulting AC kink effect at higher frequency region.

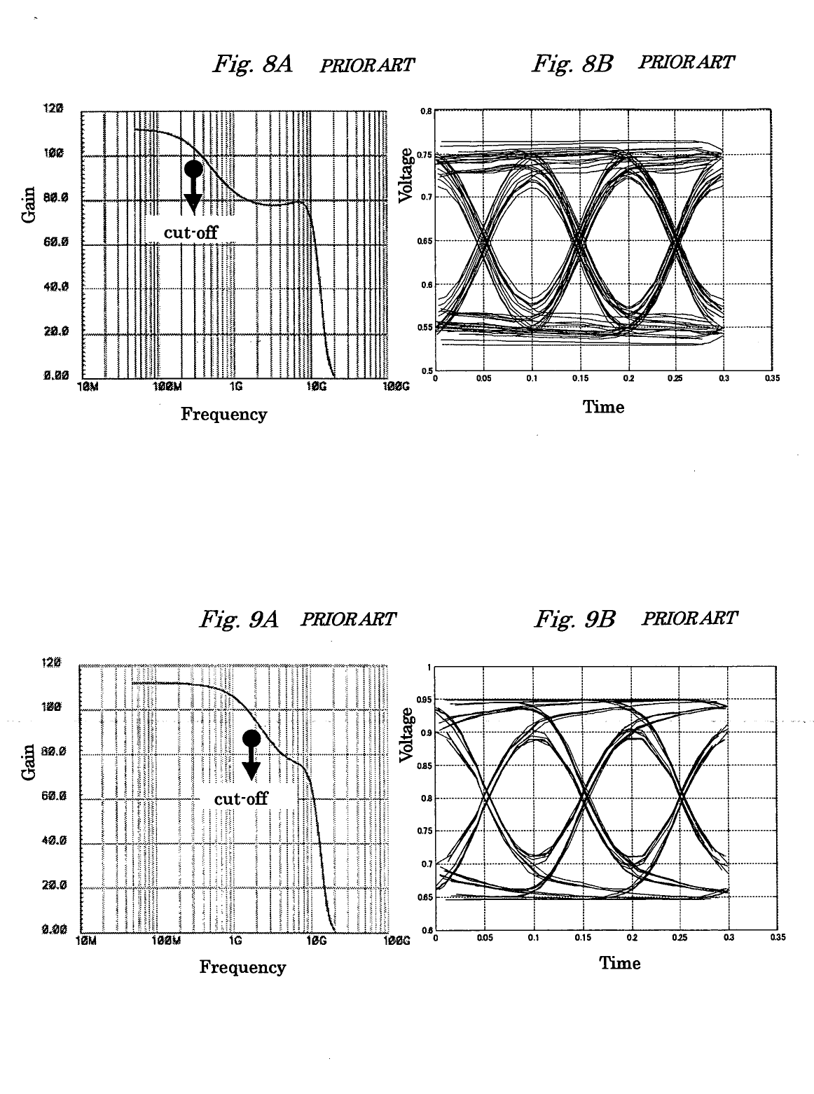

FIG. 8A is a graph showing an example of frequency characteristics due to the AC kink effect. The vertical axis shows gain (dB) and the horizontal axis shows frequency (logarithm). It can be seen from the graph that the gain decreases extremely between 1 GHz and 10 GHz with uneven frequency characteristics.

Another way to explain the gain drop at higher frequency is to view the body bode as another input. Since the signal at the drain node of the FET is the complimentary of input at the gate, the overall gain is a sum of the mutual conductance gm of the FET and the mutual conductance gm_body of the body node. On the other hand, the parasitic capacitance Cd and the parasitic body resistance Rd create a low-pass filter which filters out the coupling at frequency higher than the cut-off frequency, thereby causing the total mutual conductance to decrease.

FIG. 8B is a graph showing an example of output waveforms (eye pattern). The vertical axis shows signal intensity and the horizontal axis shows time. Fluctuation of the overall gain causes the pattern of the output waveform to jitter with fluctuation on the axis of time. To eliminate such jitters, the body resistance Rd needs to be as small as possible.

In a conventional way, smaller finger size is used so that the pattern layout of the FET has more fingers in parallel.

FIG. 9A is a graph showing an example of improved frequency characteristics using the conventional way, and FIG. 9B is a graph showing an example of output waveforms corresponding to FIG. 9A.

However, as the finger width becomes smaller, the manufacturing process is more constrained. Moreover, as the finger size becomes smaller, larger parasitic wiring capacitance is introduced.

The related prior art, e.g., Japanese Patent Unexamined Publications JP-2002-94011 A, discloses measures against electrostatic discharge in SOI integrated circuits.

The parasitic body resistance Rd in SOI structure brings adverse effect on performances of analog circuits, e.g. frequency characteristics and jitters of output waveforms. This effect becomes worse as sensitivity of buffer circuits becomes higher.

### SUMMARY OF THE INVENTION

The purpose of the present invention is to provide a high-speed differential amplifier circuit with low jitters using FETs having SOI structure, and a multistage amplifier circuit using the same.

A differential amplifier circuit according to the present invention includes:

a first field-effect transistor being operable base on a non-inverted input;

a first load circuit which is connected to the drain of the first field-effect transistor;

a first current control circuit which is connected to the source of the first field-effect transistor;

a second field-effect transistor being operable base on an inverted input;

a second load circuit which is connected to the drain of the second field-effect transistor;

a second current control circuit which is connected to the source of the second field-effect transistor; and

a gain compensation circuit which is connected between the source of the first field-effect transistor and the source of the second field-effect transistor.

Furthermore, a multistage amplifier circuit includes: a first differential amplifier circuit and a second differential amplifier circuit;

the first differential amplifier circuit including: a first field-effect transistor being operable base on a non-inverted input;

a first load circuit which is connected to the drain of the first field-effect transistor;

a first current control circuit which is connected to the source of the first field-effect transistor;

a second field-effect transistor being operable base on an inverted input;

a second load circuit which is connected to the drain of the second field-effect transistor;

a second current control circuit which is connected to the source of the second field-effect transistor; and

a gain compensation circuit which is connected between the source of the first field-effect transistor and the source of the second field-effect transistor, the second differential amplifier circuit including: a third field-effect transistor being operable base on a non-inverted input;

a third load circuit which is connected to the drain of the third field-effect transistor;

a fourth field-effect transistor being operable base on an inverted input;

a fourth load circuit which is connected to the drain of the fourth field-effect transistor; and

a third current control circuit which is connected in common to the sources of the third and fourth field-effect transistors, wherein the first and second differential amplifier circuits are connected in multistage.

In the present invention, the gain compensation circuit may include a capacitor. The capacitor may be configured of a pair of capacitive diodes which are connected with each other in parallel with reverse polarity. The gain compensation circuit may include a resistor which is connected in parallel with the capacitor.

According to the present invention, the first and second current control circuits are provided for both of the differential transistor pair and the gain compensation circuit is provided between the sources of the differential transistor pair, thereby eliminating AC kink effect at higher frequency due to such parasitic body resistance Rd and parasitic capacitance Cd as noted above. Consequently, approximately flat frequency characteristics can be attained at higher frequency, with jitters of pattern of output waveforms suppressed. BRIEF DESCRIPTION OF THE DRAWINGS

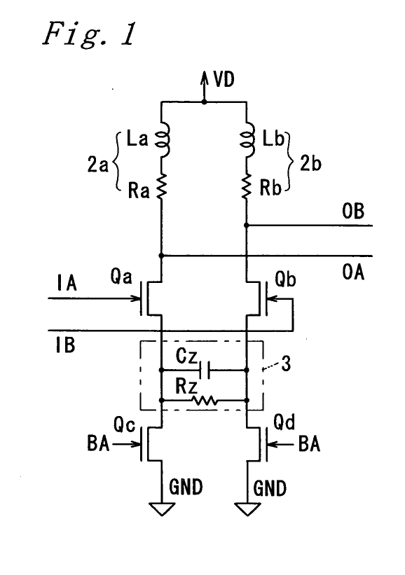

FIG. 1 is a circuit diagram showing the first embodiment of the present invention.

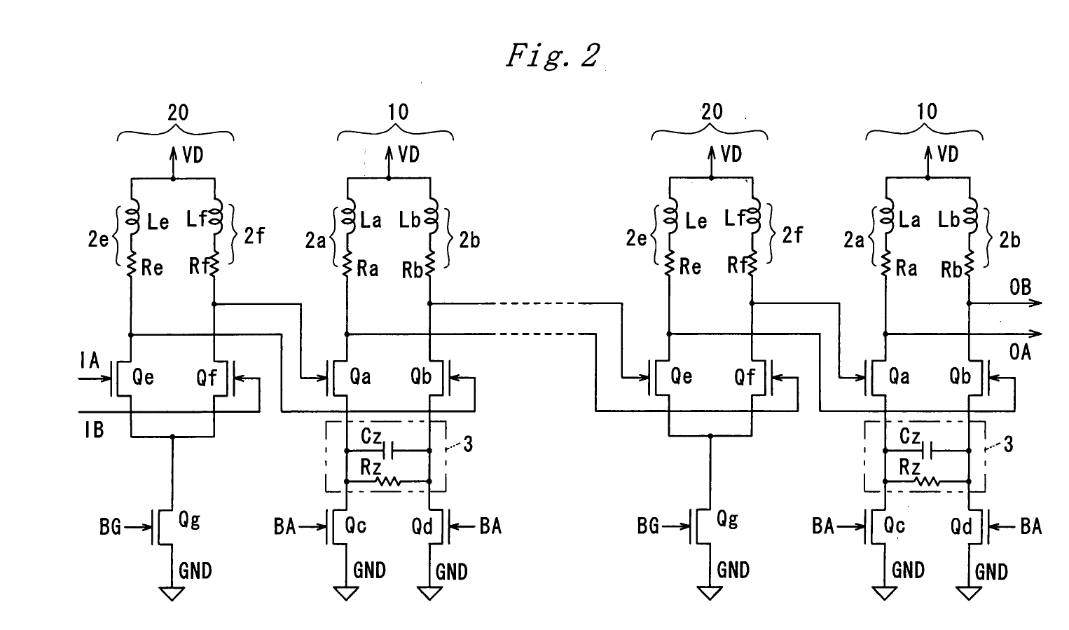

FIG. 2 is a circuit diagram showing the second embodiment of the present invention.

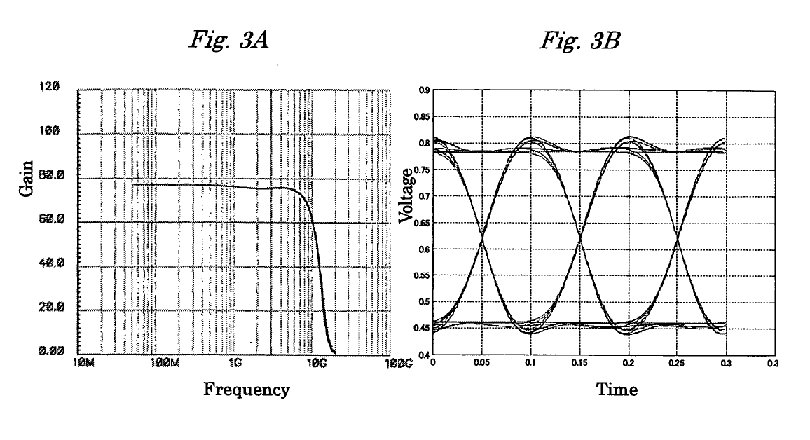

FIG. 3A is a graph showing an example of frequency characteristics of a multistage amplifier circuit, and FIG. 3B is a graph showing an example of output waveforms (eye pattern) of the multistage amplifier circuit.

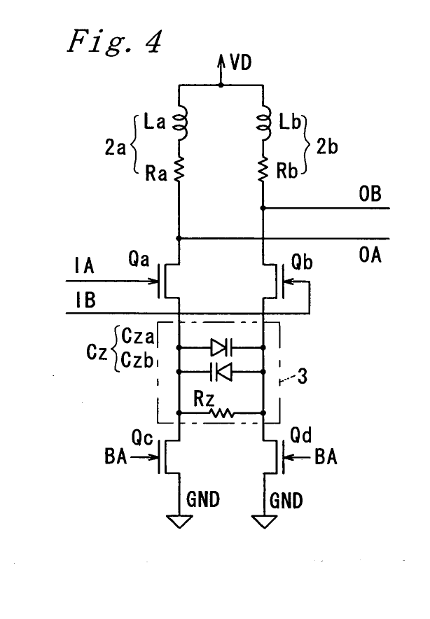

FIG. 4 is a circuit diagram showing the third embodiment of the present invention.

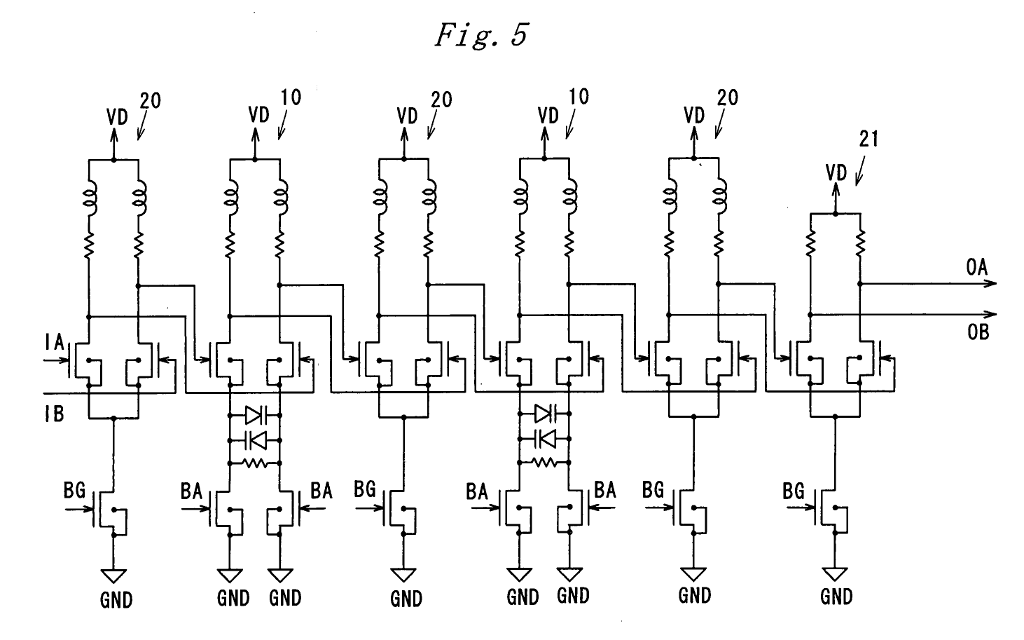

FIG. 5 is a circuit diagram showing the fourth embodiment of the present invention.

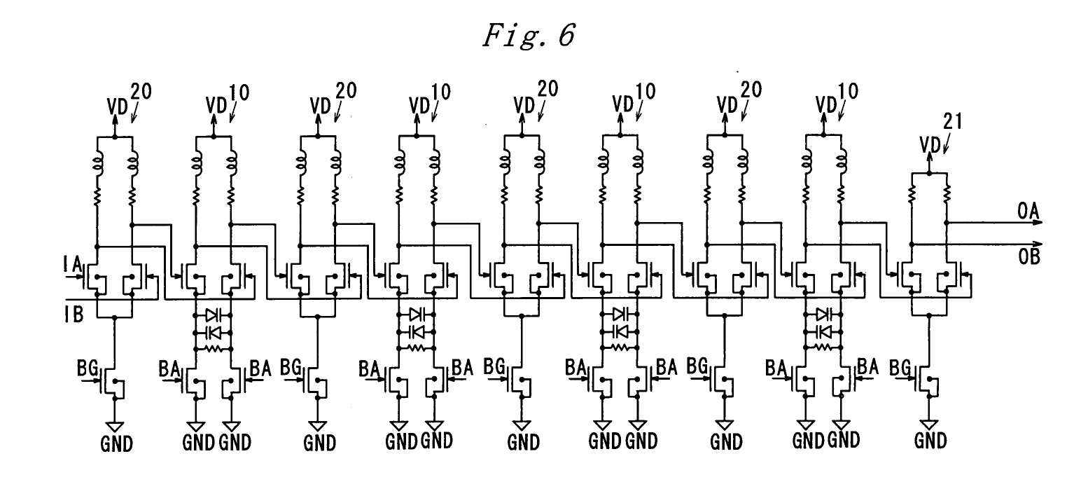

FIG. 6 is a circuit diagram showing the fifth embodiment of the present invention.

FIG. 7A is a circuit diagram showing an example of a conventional input buffer circuit, and FIG. 7B is an equivalent circuit diagram showing a parasitic capacitance and a parasitic body resistance around a MOS-FET.

FIG. 8A is a graph showing an example of frequency characteristics due to AC kink effect. FIG. 8B is a graph showing an example of output waveforms (eye pattern).

FIG. 9A is a graph showing an example of improved frequency characteristics using a conventional way, and FIG. 9B is a graph showing an example of output waveforms corresponding to FIG. 9A.

### DETAILED DESCRIPTION OF THE PREFERRED EMBODIMENTS

This application is based on an application No. 2003-374254 filed on Nov. 4, 2003 in Japan, the disclosure of which is incorporated herein by reference.

Hereinafter, preferred embodiments will be described with reference to drawings.

Embodiment 1

FIG. 1 is a circuit diagram showing the first embodiment of the present invention. A differential amplifier circuit includes a pair of field-effect transistors Qa and Qb, which can operate as differential transistor pair. The gate of the field-effect transistor Qa is supplied with an input signal IA for non-inverted input. The gate of the field-effect transistor Qb is supplied with an input signal IB for inverted input.

A load circuit 2a is connected between the drain of the field-effect transistor Qa and a power supply line VD. A load circuit 2b is connected between the drain of the field-effect transistor Qb and the power supply line VD. The load circuits 2a and 2b can be configured of various circuits, for example, herein series circuits of resistors Ra and Rb and inductors La and Lb, respectively.

Another field-effect transistor Qc is connected between the source of the field-effect transistor Qa and a ground line GND. Another field-effect transistor Qd is connected between the source of the field-effect transistor Qb and the ground line GND. When biases BA and BB of predetermined voltages are applied to the respective gates of the field-effect transistors Qc and Qd, the field-effect transistors Qc and Qd operate as current control circuits which can independently control currents flowing through the field-effect transistors Qa and Qb.

An output signal OA is led out from the connection of the field-effect transistors Qa and the load circuit 2a. An output signal OB is led out from the connection of the field-effect transistors Qb and the load circuit 2b. These output signals OA and OB are supplied into a subsequent differential amplifier circuit.

In a typical differential amplifier circuit, a single current control circuit is provided in common of sources. In this embodiment, on the other hand, a pair of current control circuits is provided correspondingly to the differential transistor pair and a gain compensation circuit 3 is arranged between the sources of the differential transistor pair.

When the field-effect transistors Qa and Qb are formed on an SOI substrate, AC kink effect at higher frequency due to parasitic body resistance Rd and parasitic capacitance Cd, as described above, takes place with a gain drop around 1 GHz as shown in FIGS. 8A and 9A. To eliminate such AC kink effect, a peaking inductor is supposed to be provided. But a large inductor (e.g. 5 nH or more) is needed for compensating the gain drop around 1 GHz, which may badly distort output waveforms due to the peaking effect.

In this embodiment, providing the gain compensation circuit 3 between the sources of the differential transistor pair can eliminate the AC kink effect at higher frequency. When a capacitor Cz is used for the gain compensation circuit 3, the circuit becomes smaller in size and easier to manufacture. In addition, circuit symmetry of differential pair can be maintained with high common mode rejection ratio (CMRR). Furthermore, choosing a value of the capacitor Cz can set up the gain compensation frequency at a desired value.

In the gain compensation circuit 3, as shown in FIG. 1, a resistor Rz may be connected in parallel to the capacitor Cz. Provision of the resistor Rz can relax gain dependence on input levels of the input signals IA and IB to linearize the input-output characteristics of the differential amplifier circuit. The resistor Rz also functions as dumping resistor which can relax peaking caused by the capacitor Cz, where choosing a value of the resistor Rz can set up the peaking height at a desired value.

Incidentally, the field-effect transistor may be configured of MOS-FET, junction type FET, or the like as long as it can be formed on a SOI substrate. In addition, a circuit including N-type FET is exemplified herein, the present invention can be applied to a differential amplifier circuit including P-type FET similarly.

Embodiment 2

FIG. 2 is a circuit diagram showing the second embodiment of the present invention. A multistage amplifier circuit includes a differential amplifier circuit 10 according to the present invention and a general differential amplifier circuit 20, which are connected in multistage, for example, to constitute an input buffer in an analog circuit.

The differential amplifier circuit 10 includes, as shown in FIG. 1, the field-effect transistor Qa being operable base on a non-inverted input, the load circuit 2a which is connected to the drain of the field-effect transistor Qa, the field-effect transistor Qc for limiting current which is connected to the source of the field-effect transistor Qa, the field-effect transistor Qb being operable base on an inverted input; the load circuit 2b which is connected to the drain of the field-effect transistor Qb, the field-effect transistor Qd for limiting current which is connected to the source of the field-effect transistor Qb, and the gain compensation circuit 3 which is connected between the sources of the field-effect transistors Qa and Qb.

The differential amplifier circuit 20 includes a pair of field-effect transistors Qe and Qf, which can operate as differential transistor pair. The gate of the field-effect transistor Qe is supplied with a non-inverted input. The gate of the field-effect transistor Qf is supplied with an inverted input.

A load circuit 2e is connected between the drain of the field-effect transistor Qe and the power supply line VD. A load circuit 2f is connected between the drain of the field-effect transistor Qf and the power supply line VD. The load circuits 2e and 2f can be configured of various circuits, for example, herein series circuits of resistors Re and Rf and inductors Le and Lf, respectively.

The source of the field-effect transistor Qe and the source of the field-effect transistor Qf are connected in common. Between the sources thereof and the ground line GND connected is another field-effect transistor Qg. When bias BG of a predetermined voltage is applied to the gate of the field-effect transistor Qg, the field-effect transistor Qg operates as current control circuit which can control the total current flowing through the field-effect transistors Qe and Qf.

Two output signals are led out from the connection of the field-effect transistors Qe and the load circuit 2e and the connection of the field-effect transistors Qf and the load circuit 2f, respectively. These output signals are supplied into a subsequent differential amplifier circuit.

The differential amplifier circuit 20 has a single current control circuit as current source, while the differential amplifier circuit 10 has a pair of current control circuits as current sources corresponding to the differential transistor pair. Therefore, in the differential amplifier circuit 10 the AC kink effect at higher frequency can be eliminated by the gain compensation circuit 3, but a differential error due to variation of characteristics of the field-effect transistors Qc and Qd may occurs with common mode noise and offset voltage.

In this embodiment, the differential amplifier circuits 10 and 20 are alternately connected in multistage, where a differential error resulting from the differential amplifier circuit 10 can be compensated by the differential amplifier circuit 20, thereby ensuring good frequency characteristics and high common mode rejection ratio (CMRR) for the whole multistage amplifier circuit.

Incidentally, when the differential amplifier circuits 10 and 20 are connected in multistage, it is preferable that they are arranged alternately. Otherwise, the number of stages and the arrangement of the differential amplifier circuits 10 and 20 may be decided in consideration of balance between frequency characteristics and common mode rejection ratio as a whole.

In addition, values of the capacitor Cz and the resistor Rz which can decide the characteristics of the gain compensation circuit 3 in each the differential amplifier circuit 10 may be the same in all the stages. Otherwise, the respective values of the capacitor Cz and the resistor Rz of the gain compensation circuit 3 may be appropriately adjusted stage by stage to attain more precise gain compensation.

FIG. 3A is a graph showing an example of frequency characteristics of the multistage amplifier circuit. The vertical axis shows gain (dB) and the horizontal axis shows frequency (logarithm). It can be seen from the graph that the flat frequency characteristics reaching approximately 7 GHz can be obtained.

FIG. 3B is a graph showing an example of output waveforms (eye pattern) of the multistage amplifier circuit. The vertical axis shows signal intensity and the horizontal axis shows time. It can be seen from the eye pattern that jitters are greatly reduced as compared to the conventional circuit.

Embodiment 3

FIG. 4 is a circuit diagram showing the third embodiment of the present invention, which exemplifies that capacitive diodes Cza and Czb, such as varactor or variable capacitance diode, are employed for the capacitor Cz of the gain compensation circuit 3.

A differential amplifier circuit includes a pair of field-effect transistors Qa and Qb, which can operate as differential transistor pair. The gate of the field-effect transistor Qa is supplied with an input signal IA for non-inverted input. The gate of the field-effect transistor Qb is supplied with an input signal IB for inverted input.

A load circuit 2a is connected between the drain of the field-effect transistor Qa and a power supply line VD. A load circuit 2b is connected between the drain of the field-effect transistor Qb and the power supply line VD. The load circuits 2a and 2b.can be configured of various circuits, for example, herein series circuits of resistors Ra and Rb and inductors La and Lb, respectively.

Another field-effect transistor Qc is connected between the source of the field-effect transistor Qa and a ground line GND. Another field-effect transistor Qd is connected between the source of the field-effect transistor Qb and the ground line GND. When biases BA and BB of predetermined voltages are applied to the respective gates of the field-effect transistors Qc and Qd, the field-effect transistors Qc and Qd operate as current control circuits which can independently control currents flowing through the field-effect transistors Qa and Qb.

An output signal OA is led out from the connection of the field-effect transistors Qa and the load circuit 2a. An output signal OB is led out from the connection of the field-effect transistors Qb and the load circuit 2b. These output signals OA and OB are supplied into a subsequent differential amplifier circuit.

In a typical differential amplifier circuit, a single current control circuit is provided in common of sources. In this embodiment, on the other hand, a pair of current control circuits is provided correspondingly to the differential transistor pair and a gain compensation circuit 3 is arranged between the sources of the differential transistor pair.

The gain compensation circuit 3 includes a parallel circuit configured of the pair of capacitive diodes Cza and Czb for the capacitor Cz and the resistor Rz.

Under an existent SOI process, a capacitive diode using p-n junction of a semiconductor is generally employed for a capacitor rather than a metal-metal capacitor. In addition, since voltage between sources of the differential transistor pair is substantially zero on account of circuit symmetry, electric capacitance Cₜₒₜₐₗ of the capacitive diode can be expressed as the following equation.

$$\frac{1}{{C}_{total}} = \frac{1}{{C}_{ox}} + \sqrt{\frac{kT}{{ɛ}_{si} {q}^{2} {N}_{a}}}$$

wherein Cₒₓ is electric capacitance of oxide film, εₛᵢ is dielectric constant of silicon, q is elementary charge, Na is carrier concentration, k is Boltzmann constant, and T is temperature. In practice, the electric capacitance Cₜₒₜₐₗ may be approximated to Cₒₓ.

Since the capacitive diode is a asymmetric device in polarity, the capacitive diodes Cza and Czb are connected in parallel with reverse polarity to each other, thereby maintaining circuit symmetry and high common mode rejection ratio (CMRR). Furthermore, utilization of such a capacitor Cz configured of the capacitive diodes Cza and Czb can eliminate the AC kink effect at higher frequency as described above.

In the gain compensation circuit 3, as shown in FIG. 4, parallel connection of the resistor Rz to the capacitor Cz can linearize input-output characteristics of the differential amplifier circuit. The resistor Rz also functions as dumping resistor which can relax peaking caused by the capacitor Cz.

In addition, appropriate adjustment of the respective values of the combined capacitance Cz of the capacitive diodes Cza and Czb and the resistor Rz can set up the peaking frequency or the peaking height at a desired value.

The above differential amplifier circuit can constitute a multistage differential amplifier circuit as shown in FIG. 2.

Embodiment 4

FIG. 5 is a circuit diagram showing the fourth embodiment of the present invention. This multistage amplifier circuit includes, similarly to the configuration in FIG. 2, a differential amplifier circuit 10 according to the present invention and a general differential amplifier circuit 20, which are connected in multistage. Herein, a five-stage amplifier circuit configured of, in sequence from the first stage, the differential amplifier circuit 20, the differential amplifier circuit 10, the differential amplifier circuit 20, the differential amplifier circuit 10 and the differential amplifier circuit 20, and an output buffer circuit 21 are provided, for example, to constitute an input buffer in an analog circuit.

In the differential amplifier circuits 10 and 20, the field-effect transistors are MOS-FETs formed on a SOI substrate, where each resistor is about 50 to 80 ohm and each inductor is about 1 nH in the load circuit of each field-effect transistor. In the differential amplifier circuit 10, a pair of capacitive diodes which are connected in parallel with reverse polarity to each other is employed for the capacitor Cz of the gain compensation circuit 3.

This five-stage input buffer has a gain of about 30 dB and frequency bandwidth reaching 6.5 GHz (−1 dB).

Embodiment 5

FIG. 6 is a circuit diagram showing the fifth embodiment of the present invention. This multistage amplifier circuit includes, similarly to the configuration in FIG. 2, a differential amplifier circuit 10 according to the present invention and a general differential amplifier circuit 20, which are connected in multistage. Herein, an eight-stage amplifier circuit configured of, in sequence from the first stage, the differential amplifier circuit 20, the differential amplifier circuit 10, the differential amplifier circuit 20, the differential amplifier circuit 10, the differential amplifier circuit 20, the differential amplifier circuit 10, the differential amplifier circuit 20 and the differential amplifier circuit 10, and an output buffer circuit 21 are provided, for example, to constitute an input buffer in an analog circuit.

In the differential amplifier circuits 10 and 20, the field-effect transistors are MOS-FETs formed on a SOI substrate, where each resistor is about 50 to 100 ohm and each inductor is about 850 pH in the load circuit of each field-effect transistor. In the differential amplifier circuit 10, a pair of capacitive diodes which are connected in parallel with reverse polarity to each other is employed for the capacitor Cz of the gain compensation circuit 3.

This eight-stage input buffer has a gain of about 40 dB and frequency bandwidth reaching 7.5 GHz (−1 dB).

Although the present invention has been fully described in connection with the preferred embodiments thereof and the accompanying drawings, it is to be noted that various changes and modifications are apparent to those skilled in the art. Such changes and modifications are to be understood as included within the scope of the present invention as defined by the appended claims unless they depart therefrom.

1. A differential amplifier circuit comprising:
a first field-effect transistor being operable base on a non-inverted input;
a first load circuit which is connected to the drain of the first field-effect transistor;
a first current control circuit which is connected to the source of the first field-effect transistor;
a second field-effect transistor being operable base on an inverted input;
a second load circuit which is connected to the drain of the second field-effect transistor;
a second current control circuit which is connected to the source of the second field-effect transistor; and
a gain compensation circuit which is connected between the source of the first field-effect transistor and the source of the second field-effect transistor.

2. The differential amplifier circuit according to claim 1, wherein the gain compensation circuit includes a capacitor.

3. The differential amplifier circuit according to claim 2, wherein the capacitor is configured of a pair of capacitive diodes which are connected with each other in parallel with reverse polarity.

4. The differential amplifier circuit according to claim 2, wherein the gain compensation circuit includes a resistor which is connected in parallel with the capacitor.

5. The differential amplifier circuit according to claim 3, wherein the gain compensation circuit includes a resistor which is connected in parallel with the capacitor.

6. A multistage amplifier circuit comprising: a first differential amplifier circuit and a second differential amplifier circuit;
the first differential amplifier circuit including: a first field-effect transistor being operable base on a non-inverted input;
a first load circuit which is connected to the drain of the first field-effect transistor;
a first current control circuit which is connected to the source of the first field-effect transistor;
a second field-effect transistor being operable base on an inverted input;
a second load circuit which is connected to the drain of the second field-effect transistor;
a second current control circuit which is connected to the source of the second field-effect transistor; and
a gain compensation circuit which is connected between the source of the first field-effect transistor and the source of the second field-effect transistor,
the second differential amplifier circuit including: a third field-effect transistor being operable base on a non-inverted input;
a third load circuit which is connected to the drain of the third field-effect transistor;
a fourth field-effect transistor being operable base on an inverted input;
a fourth load circuit which is connected to the drain of the fourth field-effect transistor; and
a third current control circuit which is connected in common to the sources of the third and fourth field-effect transistors,
wherein the first and second differential amplifier circuits are connected in multistage.

7. The multistage amplifier circuit according to claim 6, wherein the gain compensation circuit includes a capacitor.

8. The multistage amplifier circuit according to claim 7, wherein the capacitor is configured of a pair of capacitive diodes which are connected with each other in parallel with reverse polarity.

9. The multistage amplifier circuit according to claim 7, wherein the gain compensation circuit includes a resistor which is connected in parallel with the capacitor.

10. The multistage amplifier circuit according to claim 8, wherein the gain compensation circuit includes a resistor which is connected in parallel with the capacitor.
